(19) United States
(12) Patent Application Publication
(10) Pub. No.: US 2022/0216255 A1
(43) Pub. Date: Jul. 7, 2022

(54) IMAGE SENSOR PACKAGE HAVING INNER AND OUTER JOINT MEMBERS

(71) Applicant: SEMICONDUCTOR COMPONENTS INDUSTRIES, LLC, Phoenix, AZ (US)

(72) Inventor: Yu-Te HSIEH, Taoyuan City (TW)

(73) Assignee: SEMICONDUCTOR COMPONENTS INDUSTRIES, LLC, Phoenix, AZ (US)

(21) Appl. No.: 17/143,341

(22) Filed: Jan. 7, 2021

(51) Int. Cl. H01L 27/146

(52) U.S. Cl. CPC H01L 27/14618; H01L 27/14643; H01L 27/14689

(57) ABSTRACT

According to an aspect, an image sensor package includes a substrate, an image sensor die coupled to the substrate, a light-transmitting member, an inner joint member disposed between the light-transmitting member and the image sensor die, and an outer joint member disposed between the light-transmitting member and the substrate.

### TECHNICAL FIELD

This description relates to an image sensor package having inner and outer joint members.

### BACKGROUND

An image sensor package may use a bonding material to couple a glass substrate to an image sensor die. Also, the bonding material may operate as a dam member in which the bonding material positions the glass substrate at a location away from an active area of the image sensor die, the bonding material is disposed on a non-active area of the image sensor die. However, for some applications, the non-active area may be relatively small, thereby making the glass bonding process more difficult. In addition, some image sensor packages use wire bonding to couple the substrate to the image sensor die. However, as the number of pin counts increase (e.g., due to the increased functionalities of devices), the cost of using bond wires to connect the image sensor die to the substrate may be relatively high.

### SUMMARY

According to an aspect, an image sensor package includes a substrate, an image sensor die coupled to the substrate, a light-transmitting member, an inner joint member disposed between the light-transmitting member and the image sensor die, and an outer joint member disposed between the light-transmitting member and the substrate.

According to some aspects, the image sensor package may include one or more of the following features (or any combination thereof). The image sensor package includes a conductive trace coupled to a surface of the light-transmitting member, where the conductive trace is coupled to the inner joint member and the outer joint member. The image sensor die is coupled to the substrate in a flip-chip configuration. The inner joint member has a size smaller than a size of the outer joint member. The inner joint member may include a conductive ball member. The inner joint member may include a conductive pillar. The outer joint member may include a conductive ball member. The image sensor package may include an encapsulation material disposed between the inner joint member and the outer joint member. The image sensor package is an interstitial ball grid array (iBGA) package.

According to an aspect, an image sensor package includes a substrate, an image sensor die coupled to the substrate, where the image sensor die has an active region and a non-active region, a light-transmitting member having a first surface and second surface, a conductive trace coupled to the second surface of the light-transmitting member, an inner joint member disposed between and connected to the non-active region of the image sensor die and the conductive trace, and an outer joint member disposed between and connected to the conductive trace and the substrate.

According to some aspects, the image sensor package may include one or more of the following features (or any combination thereof). The image sensor die is a complementary metal oxide semiconductor (CMOS) image sensor die, and the CMOS image sensor die is coupled to the substrate in a flip-chip configuration. The inner joint member includes a conductive ball member. The inner joint member includes a conductive pillar. The outer joint member includes a conductive ball member. The image sensor package may include an encapsulation material, where the encapsulation material includes an inner molding disposed between the inner joint member and the outer joint member. The encapsulation material includes an outer molding that contacts edges of the light-transmitting member. The substrate includes a first surface and a second surface, where the first surface of the substrate is coupled to the image sensor die. The image sensor package includes a plurality of conductive components coupled to the second surface of the substrate, where the plurality of conductive components are configured to be coupled to an external device. The image sensor package is devoid of bond wires.

According to an aspect, a method for assembling an image sensor package includes forming a conductive trace on a light-transmitting member via a lithography process, coupling an inner joint member to a first portion of the conductive trace, coupling an image sensor die to the inner joint member, coupling an outer joint member to a second portion of the conductive trace, and coupling a substrate to the outer joint member and the image sensor die. In some examples, the method may include applying an encapsulation material to the image sensor package, where the encapsulation material includes an inner molding disposed between the outer joint member and the inner joint member. The inner joint member may include a conductive ball member or a conductive pillar, and the outer joint member includes a conductive ball member.

The details of one or more implementations are set forth in the accompanying drawings and the description below. Other features will be apparent from the description and drawings, and from the claims.

### BRIEF DESCRIPTION OF THE DRAWINGS

FIG. 1 illustrates an image sensor package according to an aspect.

FIG. 2 illustrates an image sensor package according to another aspect.

FIG. 3 illustrates an image sensor package according to another aspect.

FIGS. 4A through 4I illustrate a process flow for assembling an image sensor package according to an aspect.

FIG. 5 illustrates a flowchart depicting example operations of assembling an image sensor package according to an aspect.

### DETAILED DESCRIPTION

The present disclosure relates to an image sensor package that uses inner lead joint and outer lead joints to position a light-transmitting member away from an active region of an image sensor die and to couple the image sensor die to a substrate in a flip-chip configuration. In this manner, the use of a bonding material as a dam to position the light-transmitting member away from the image sensor die can be avoided, thereby avoiding the difficulties associated with a bonding process with the dam on the image sensor die. In some examples, the image sensor packages discussed herein may avoid the use of bond wires, thereby can decrease the cost of making such packages. Furthermore, the use of the inner lead joint and outer lead joints may increase the durability of an image sensor package.

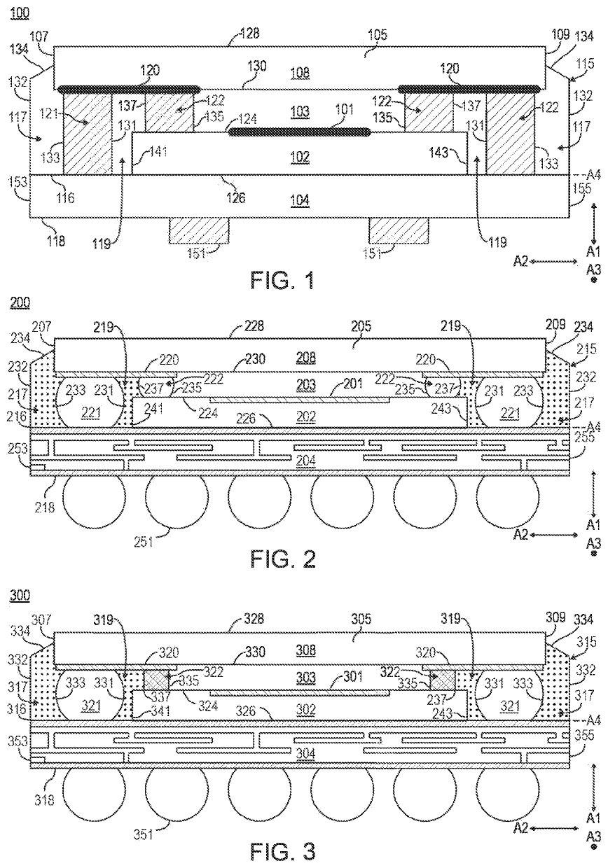

FIG. 1 illustrates an image sensor package 100 according to an aspect. In some examples, the image sensor package 100 includes an interstitial ball grid array (iBGA) package. In some examples, the image sensor package 100 is an automobile image sensor (e.g., an image sensor designed to be incorporated into a vehicle). However, the image sensor package 100 may be applicable to other types of applications. The image sensor package 100 includes a substrate 104, an image sensor die 102 coupled to the substrate 104, a light-transmitting member 108, inner joint members 122 disposed between the light-transmitting member 108 and the image sensor die 102, and outer joint members 121 disposed between the light-transmitting member 108 and the substrate 104. The image sensor package 100 includes conductive components 151 coupled to the substrate 104, where the conductive components 151 are configured to connect to an external device. The image sensor package 100 includes an encapsulation material 115 having an outer molding 117 that contacts the outer joint members 121, the substrate 104, and the light-transmitting member 108, and an inner molding 119 that is disposed between the outer joint members 121 and the inner joint members 122.

The substrate 104 includes a dielectric material. In some examples, the substrate 104 includes a single layer of dielectric material. In some examples, the substrate 104 includes multiple layers of dielectric material. In some examples, the substrate 104 includes a printed circuit board (PCB) substrate (e.g., a single layer of PCB or multiple layers of PCB). In some examples, the substrate 104 includes a copper clad laminate (CCL) substrate.

The substrate 104 includes a first surface 116 and a second surface 118 that is disposed opposite to the first surface 116. The second surface 118 may be parallel with the first surface 116. The distance between the first surface 116 and the second surface 118 may define the thickness of the substrate 104 in a direction A1. The substrate 104 includes a first edge 153 and a second edge 155. The second edge 155 may be parallel to the first edge 153. The first edge 153 and the second edge 155 may be perpendicular to the first surface 116 and the second surface 118. The distance between the first edge 153 and the second edge 155 may define a length of the substrate 104 in a direction A2. The first surface 116 of the substrate 104 is disposed in a plane A4. A direction A1 is aligned perpendicular to the plane A4, and a direction A2 is perpendicular to the direction A1. A direction A3 into the page (shown as a dot) is aligned parallel to the plane A4 and is orthogonal to directions A1 and A2. The directions A1, A2, and A3, and plane A4, are used throughout several of the various views of the implementations described throughout the figures for simplicity.

In some examples, the substrate 104 includes one or more conductive layer portions (e.g., traces) disposed on the first surface 116 of the substrate 104, and/or one or more conductive layer portions (e.g., traces) disposed on the second surface 118 of the substrate 104. In some examples, the one or more conductive layer portions on the substrate 104 include electrical (or conductive) traces. The electrical traces may be configured to and/or used to transmit signals to and/or from devices (e.g., electronic devices included in a semiconductor region (e.g., epitaxial layer and/or semiconductor substrate)) connected to the electrical traces. In some examples, the electrical traces can include conductive traces (e.g., metallic traces) such as copper traces, aluminum traces, and/or so forth. In some examples, the electrical traces include a relatively flat, narrow part of a copper foil that remains after etching. In some examples, the substrate 104 is a CCL substrate with copper traces (on both surfaces) with a pre-preg core (e.g., pre-impregnated with resin), where the copper traces are formed by photolithography patterning from a copper foil.

The image sensor die 102 includes a first surface 124 and a second surface 126. The second surface 126 is disposed in parallel with the first surface 124. The distance between the first surface 124 and the second surface 126 may define the thickness of the image sensor die 102 in the direction A1. The image sensor die 102 includes a first edge 141 and a second edge 143. The second edge 143 is disposed in parallel with the first edge 141. The distance between the first edge 141 and the second edge 143 may define a length of the image sensor die 102 in the direction A2.

The image sensor die 102 includes an active region 101. The active region 101 is defined on a portion of the first surface 124 of the image sensor die 102. The active region 101 includes, or corresponds with, an array of pixel elements configured to convert electromagnetic radiation (e.g., light) to electrical signals. An area outside of the active region 101 may be considered a non-active region. In some examples, the image sensor die 102 includes a complementary metal-oxide semiconductor (CMOS) image sensor. The image sensor die 102 is coupled to the substrate 104. For example, the second surface of the image sensor die 102 is coupled to the first surface 116 of the substrate 104. In some examples, the image sensor die 102 is coupled to the substrate 104 via a bonding material (e.g., a die attach film). The image sensor die 102 is coupled to the substrate 104 in a flip-chip configuration (e.g., using the inner joint members 122 and the outer joint members 121, and conductive traces 120 that connect the outer joint members 121 to the inner joint members 122).

The light-transmitting member 108 is coupled to the image sensor die 102 such that the light-transmitting member 108 is positioned over (and spaced apart from) the active region 101 of the image sensor die 102 in the direction A1. The light-transmitting member 108 includes a first surface 128 and a second surface 130. The second surface 130 is disposed in parallel with the first surface 128. The distance between the first surface 128 and the second surface 130 may define the thickness of the light-transmitting member 108 in the direction A1. The light-transmitting member 108 includes a first edge 107 and a second edge 109. The second edge 109 is disposed in parallel with the first edge 107. The distance between the first edge 107 and the second edge 109 may define a length of the light-transmitting member 108 in the direction A2.

The light-transmitting member 108 may include an optically transparent material that allows electromagnetic radiation (e.g., light (e.g., visible light)) to pass through (e.g., pass through the entirety of the material). In some examples, the light-transmitting member 108 includes a glass substrate. In some examples, the light-transmitting member 108 includes a transparent (or semi-transparent) cover. In some examples, the light-transmitting member 108 includes a transparent (or semi-transparent) lid. In some examples, the light-transmitting member 108 includes one or more organic materials and/or one or more inorganic materials. In some examples, the light-transmitting member 108 includes one or more layers of transparent material.

Conductive traces 120 are coupled to the light-transmitting member 108. Conductive traces 120 are coupled to the second surface 130 of the light-transmitting member 108. The conductive traces 120 may be metallic traces such as copper traces, aluminum traces, and/or so forth. In some examples, a conductive trace 120 includes multiple types of metals. In some examples, the conductive traces 120 are formed on the light-transmitting member 108 via a lithography process. In some examples, a conductive trace 120 is coupled to the second surface 130 at a location between the first edge 107 and a central region 105 of the light-transmitting member 108, and a conductive trace 120 is coupled to the second surface 130 at a location between the second edge 109 and the central region 105. The central region 105 is an area of the light-transmitting member 108 that is devoid of conductive traces 120. The central region 105 is an area of the light-transmitting member 108 that passes light to the active region 101 of the image sensor die 102.

The outer joint members 121 and the inner joint members 122 are used to position the light-transmitting member 108 away from the active region 101 of the image sensor die 102 to route signals from the image sensor die 102 to the substrate 104. The inner joint members 122 may be conductive (rigid) structures that connect to the image sensor die 102 and the conductive traces 120 on the light-transmitting member 108. The inner joint members 122 may include one or more types of metallic materials. In some examples, the inner joint members 122 include conductive balls (e.g., solder balls). In some examples, the inner joint members 122 include conductive pillars (e.g., copper pillars). The outer joint members 121 may be conductive (rigid) structures that connect to the substrate 104 and the conductive traces 120 on the light-transmitting member 108. In some examples, the outer joint members 121 include conductive balls (e.g., solder balls). In some examples, the outer joint members 121 include conductive pillars (e.g., copper pillars). In some examples, the outer joint members 121 are solder balls, and the inner joint members 122 are copper pillars. The outer joint members 121 may extend around a perimeter area of the substrate 104. For example, there may be outer joint members 121 positioned in the direction A3. The inner joint members 122 may extend around a perimeter area of the image sensor die 102. For example, there may be inner joint members 122 positioned in the direction A3. The outer joint members 121 may be positioned around the perimeter of the inner joint members 122.

The inner joint members 122 are coupled to the first surface 124 of the image sensor die 102 and the conductive traces 120 on the light-transmitting member 108. The inner joint members 122 may be coupled to the non-active area of the image sensor die 104. The inner joint members 122 include an inner edge 135 and an outer edge 137. In some examples, a conductive trace 120 may be coupled to the first surface 124 at a location between the first edge 141 and the active region 101 of the image sensor die 102, and a conductive trace 120 may be coupled to the first surface 124 at a location between the second edge 143 and the active region 101 of the image sensor die 102. The height of the inner joint members 122 (in the direction A1) may define (at least in part) the gap height (e.g., the height of empty space 103 between the active region 101 and the second surface 130 of the light-transmitting member 108).

The outer joint members 121 are coupled to the first surface 116 of the substrate 104 and the conductive traces 120 on the light-transmitting member 108. The outer joint members 121 include an inner edge 131 and an outer edge 133. In some examples, a conductive trace 120 may be coupled to the first surface 116 at a location between the first edge 153 of the substrate 104 and the first edge 141 of the image sensor die 102, and a conductive trace 120 may be coupled to the first surface 116 at a location between the second edge 155 of the substrate 104 and the second edge 143 of the image sensor die 102. The height of the outer joint members 121 (in the direction A1) may define (at least in part) the distance between the first surface 116 of the substrate 104 and the second surface 130 of the light-transmitting member 108.

The outer joint members 121 may have a height greater than the height of the inner joint members 122 in the direction A2. In some examples, the outer joint members 121 may be a width greater than the width of the inner joint members 122 in the direction A2. In some examples, the height of the outer joint members 121 is equal to the combination of the height of the image sensor die 102 and the height of the inner joint members 122.

The image sensor package 100 includes conductive components 151 coupled to the second surface 118 of the substrate 104. In some examples, the conductive components 151 are surface-mount packaging elements. In some examples, the conductive components 151 include solder balls. The conductive components 151 are components used to connect to an external device (e.g., a ball grid array (BGA) device). However, the conductive components 151 may include other types of surface-mount packaging elements.

The image sensor package 100 includes an encapsulation material 115. The encapsulation material 115 may include one or more molding materials (e.g., in a molding compound if including multiple types of materials). For example, the molding material(s) may include a metal, a plastic, a resin, an epoxy, a phenolic hardener, a silica material, a pigment, a glass, a ceramic casing, and/or so forth.

The encapsulation material 115 may include an outer molding 117 that contacts the substrate 104, the outer joint members 121 and the light-transmitting member 108. For example, the outer molding 117 contacts a portion (e.g., a perimeter portion) of the first surface 116 of the substrate 104, the outer edge 133 of the outer joint members 121, and at least a portion of the first and second edges 107, 109 of the light-transmitting member 108. In some examples, the outer molding 117 extends along the entirety of the first and second edges 107, 109 of the light-transmitting member 108. In some examples, although not shown in FIG. 1, the outer molding 117 may extend and contact at least a portion of the first surface 128 of the light-transmitting member 108.

In some examples, the outer molding 117 defines a first molding edge 132 that defines an end of the outer molding 117 in the direction A2. In some examples, the first molding edge 132 is linear. In some examples, the first molding edge 132 includes one or more angled or curved portions. In some examples, at least a portion of the first molding edge 132 (or all of the first molding edge 132) is aligned with the direction A1. In some examples, the first molding edge 132 is disposed at an angle with respect to the direction A2. In some examples, at least a portion of the first molding edge 132 (or all of the first molding edge 132) is aligned with the first edge 153 (or the second edge 155) of the substrate 104. In some examples, the first molding edge 132 is disposed at a location between the first edge 153 (or the second edge 155) of the substrate 104 and the outer edge 133 of the outer joint members 121.

The outer molding 117 may define a second molding edge 134 defining an end of the outer molding 117 in the direction A1. The second molding edge 134 may extend from the first molding edge 132 to the first and second edges 107, 109 of the light-transmitting member 108. In some examples, the second molding edge 134 is disposed at a non-zero angle with respect to the first molding edge 132. In some examples, the second molding edge 134 is disposed at an angle that is perpendicular to the first molding edge 132. In some examples, the second molding edge 134 is linear. In some examples, the second molding edge 134 includes one or more bent or curved portions.

The encapsulation material 115 may include an inner molding 119 that contacts and extends between the inner joint members 122 and the outer joint members 121. For example, the inner molding 119 contacts a portion of the first surface 116 of the substrate, the inner edge 131 of the outer joint members 121, the first and second edges 141, 143 of the image sensor die 102, and the outer edge 137 of the inner joint members 122. For example, the inner molding 119 may extend between the inner edge 131 of the outer joint members 121 and the first and second edges 141, 143 of the image sensor die 102 in the direction A2. Also, the inner molding 119 may extend between the inner edge 131 of the outer joint members 121 and the inner edge 135 of the inner joint members 122 in the direction A2. The inner molding 119 may extend between the first surface 116 of the substrate 104 and the conductive traces 120 on the light-transmitting member 108 in the direction A1. In some examples, the outer molding 117 includes one or more materials different from the material of the inner molding 119. In some examples, the outer molding 117 includes one or more materials that is/are the same as the material of the inner molding 119.

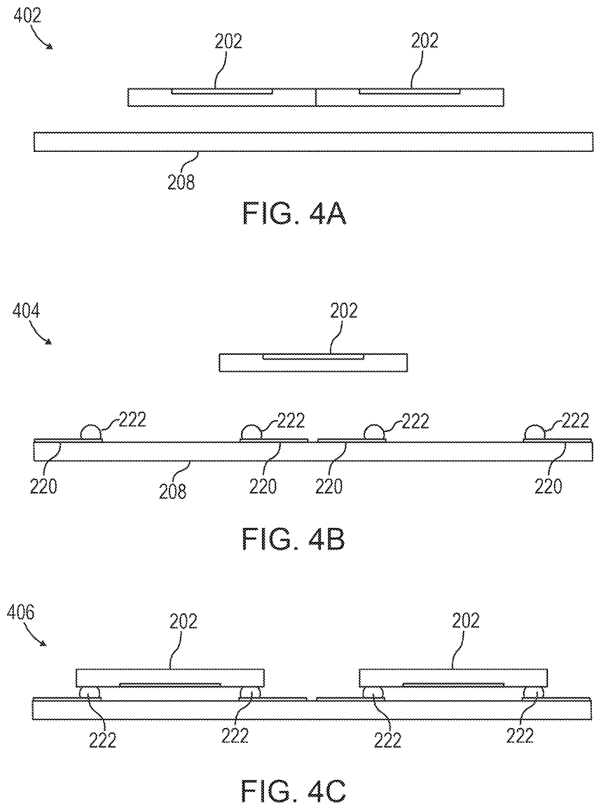

FIG. 2 illustrates an image sensor package 200 according to an aspect. The image sensor package 200 may be an example of the image sensor package 100 of FIG. 1 and may include any of the details discussed herein.

The image sensor package 200 includes a substrate 204, an image sensor die 202 coupled to the substrate 204, a light-transmitting member 208, inner joint members 222 disposed between the light-transmitting member 208 and the image sensor die 202, and outer joint members 221 disposed between the light-transmitting member 208 and the substrate 204. As shown in FIG. 2, in some examples, the inner joint members 222 may be conductive ball members (e.g., solder balls). Also, in some examples, the outer joint members 221 may be conductive ball members (e.g., solder balls). The image sensor package 200 includes conductive components 251 coupled to the substrate 204, where the conductive components 251 are configured to connect to an external device. The conductive components 251 may be conductive ball members (e.g., solder balls). The image sensor package 200 includes an encapsulation material 215 having an outer molding 217 that contacts the outer joint members 221, the substrate 204, and the light-transmitting member 208, and an inner molding 219 that is disposed between the outer joint members 221 and the inner joint members 222.

The substrate 204 includes a dielectric material. In some examples, the substrate 204 includes a single layer of dielectric material. In some examples, the substrate 204 includes multiple layers of dielectric material. In some examples, the substrate 204 includes a printed circuit board (PCB) substrate (e.g., a single layer of PCB or multiple layers of PCB). In some examples, the substrate 204 includes a copper clad laminate (CCL) substrate.

The substrate 204 includes a first surface 216 and a second surface 218 that is disposed opposite to the first surface 216. The second surface 218 may be parallel with the first surface 216. The distance between the first surface 216 and the second surface 218 may define the thickness of the substrate 204 in a direction A1. The substrate 204 includes a first edge 253 and a second edge 255. The second edge 255 may be parallel to the first edge 253. The first edge 253 and the second edge 255 may be perpendicular to the first surface 216 and the second surface 218. The distance between the first edge 253 and the second edge 255 may define a length of the substrate 204 in a direction A2.

The image sensor die 202 includes a first surface 224 and a second surface 226. The second surface 226 is disposed in parallel with the first surface 224. The distance between the first surface 224 and the second surface 226 may define the thickness of the image sensor die 202 in the direction A1. The image sensor die 202 includes a first edge 241 and a second edge 243. The second edge 243 is disposed in parallel with the first edge 241. The distance between the first edge 241 and the second edge 243 may define a length of the image sensor die 202 in the direction A2.

The image sensor die 202 includes an active region 201. The active region 201 is defined on a portion of the first surface 224 of the image sensor die 202. The active region 201 includes, or corresponds with, an array of pixel elements configured to convert electromagnetic radiation (e.g., light) to electrical signals. An area outside of the active region 201 may be considered a non-active region. In some examples, the image sensor die 202 includes a complementary metal-oxide semiconductor (CMOS) image sensor. The image sensor die 202 is coupled to the substrate 204. For example, the second surface of the image sensor die 202 is coupled to the first surface 216 of the substrate 204. In some examples, the image sensor die 202 is coupled to the substrate 204 via a bonding material (e.g., a die attach film). The image sensor die 202 is coupled to the substrate 204 in a flip-chip configuration (e.g., using the inner joint members 222 and the outer joint members 221, and conductive traces 220 that connect the outer joint members 221 to the inner joint members 222).

The light-transmitting member 208 is coupled to the image sensor die 202 such that the light-transmitting member 208 is positioned over (and spaced apart from) the active region 201 of the image sensor die 202 in the direction A1. The light-transmitting member 208 includes a first surface 228 and a second surface 230. The second surface 230 is disposed in parallel with the first surface 228. The distance between the first surface 228 and the second surface 230 may define the thickness of the light-transmitting member 208 in the direction A2. The light-transmitting member 208 includes a first edge 207 and a second edge 209. The second edge 209 is disposed in parallel with the first edge 207. The distance between the first edge 207 and the second edge 209 may define a length of the light-transmitting member 208 in the direction A2.

Conductive traces 220 are coupled to the light-transmitting member 208. Conductive traces 220 are coupled to the second surface 230 of the light-transmitting member 208. The conductive traces 220 may be metallic traces such as copper traces, aluminum traces, and/or so forth. In some examples, a conductive trace 220 includes multiple types of metals. In some examples, the conductive traces 220 are formed on the light-transmitting member 208 via a lithography process. In some examples, a conductive trace 220 is coupled to the second surface 230 at a location between the first edge 207 and a central region 205 of the light-transmitting member 208, and a conductive trace 220 is coupled to the second surface 230 at a location between the second edge 209 and the central region 205. The central region 205 is an area of the light-transmitting member 208 that is devoid of conductive traces 220. The central region 205 is an area of the light-transmitting member 208 that passes light to the active region 201 of the image sensor die 202.

The outer joint members 221 and the inner joint members 222 are used to position the light-transmitting member 208 away from the active region 201 of the image sensor die 202 to route (e.g., electrically route) signals from the image sensor die 202 to the substrate 204. As shown in FIG. 2, the outer joint members 221 and the inner joint members 222 are conductive ball members (e.g., solder balls). In some examples, the conductive ball members may be referred to as conductive (solder) bumps. In some examples, the conductive ball members have a spherical shape, where the ends of the spherical ball may be relatively flat to increase contact with the other components. The conductive ball members of the outer joint members 221 may have a size (e.g., diameter, height in the direction A1, and/or width in the direction A2) that is larger than the size of the conductive ball members of the inner joint members 222.

The inner joint members 222 are coupled to the first surface 224 of the image sensor die 202 and the conductive traces 220 on the light-transmitting member 208. The inner joint members 222 may be coupled to the non-active area of the image sensor die 204. The inner joint members 222 include an inner edge 235 and an outer edge 237. The inner edge 235 may include a curved portion. The outer edge 237 may include a curved portion. In some examples, a conductive trace 220 may be coupled to the first surface 224 at a location between the first edge 241 and the active region 201 of the image sensor die 202, and a conductive trace 220 may be coupled to the first surface 224 at a location between the second edge 243 and the active region 201 of the image sensor die 202. The height of the inner joint members 222 (in the direction A1) may define (at least in part) the gap height (e.g., the height of empty space 203 between the active region 201 and the second surface 230 of the light-transmitting member 208).

The outer joint members 221 are coupled to the first surface 216 of the substrate 204 and the conductive traces 220 on the light-transmitting member 208. The outer joint members 221 include an inner edge 231 and an outer edge 233. The inner edge 231 may include a curved portion. The outer edge 233 may include a curved portion. In some examples, a conductive trace 220 may be coupled to the first surface 216 at a location between the first edge 253 of the substrate 204 and the first edge 241 of the image sensor die 202, and a conductive trace 220 may be coupled to the first surface 216 at a location between the second edge 255 of the substrate 204 and the second edge 243 of the image sensor die 202. The height of the outer joint members 221 (in the direction A1) may define (at least in part) the distance between the first surface 216 of the substrate 204 and the second surface 230 of the light-transmitting member 208. The outer joint members 221 may have a height greater than the height of the inner joint members 222 in the direction A2. In some examples, the outer joint members 221 may be a width greater than the width of the inner joint members 222 in the direction A2.

The image sensor package 200 includes conductive components 251 coupled to the second surface 218 of the substrate 204. In some examples, the conductive components 251 are surface-mount packaging elements. In some examples, the conductive components 251 include solder balls. The conductive components 251 are components used to connect to an external device (e.g., a ball grid array (BGA) device). However, the conductive components 251 may include other types of surface-mount packaging elements. In some examples, the conductive components 251, the inner joint members 222, and the outer joint members 221 are conductive (solder) balls, which may include the same type of material(s). In some examples, the conductive components 251 have a size that is larger than the inner joint members 222 and smaller than the outer joint members 221.

The image sensor package 200 includes an encapsulation material 215. The encapsulation material 215 may include one or more molding materials (e.g., in a molding compound if including multiple types of materials). For example, the molding material(s) may include a metal, a plastic, a resin, an epoxy, a phenolic hardener, a silica material, a pigment, a glass, a ceramic casing, and/or so forth.

The encapsulation material 215 may include an outer molding 217 that contacts the substrate 204, the outer joint members 221 and the light-transmitting member 208. For example, the outer molding 217 contacts a portion (e.g., a perimeter portion) of the first surface 216 of the substrate 204, the outer edge 233 of the outer joint members 221, and at least a portion of the first and second edges 207, 209 of the light-transmitting member 208. In some examples, the outer molding 217 extends along the entirety of the first and second edges 207, 209 of the light-transmitting member 208. In some examples, although not shown in FIG. 2, the outer molding 217 may extend and contact at least a portion of the first surface 228 of the light-transmitting member 208.

In some examples, the outer molding 217 defines a first molding edge 232 that defines an end of the outer molding 217 in the direction A2. In some examples, the first molding edge 232 is linear. In some examples, the first molding edge 232 includes one or more angled or curved portions. In some examples, at least a portion of the first molding edge 232 (or all of the first molding edge 232) is aligned with the direction A1. In some examples, the first molding edge 232 is disposed at an angle with respect to the direction A2. In some examples, at least a portion of the first molding edge 232 (or all of the first molding edge 232) is aligned with the first edge 253 (or the second edge 255) of the substrate 204. In some examples, the first molding edge 232 is disposed at a location between the first edge 253 (or the second edge 255) of the substrate 204 and the outer edge 233 of the outer joint members 221.

The outer molding 217 may define a second molding edge 234 defining an end of the outer molding 217 in the direction A1. The second molding edge 234 may extend from the first molding edge 232 to the first and second edges 207, 209 of the light-transmitting member 208. In some examples, the second molding edge 234 is disposed at a non-zero angle with respect to the first molding edge 232. In some examples, the second molding edge 234 is disposed at an angle that is perpendicular to the first molding edge 232. In some examples, the second molding edge 234 is linear. In some examples, the second molding edge 234 includes one or more bent or curved portions.

The encapsulation material 215 may include an inner molding 219 that contacts and extends between the inner joint members 222 and the outer joint members 221. For example, the inner molding 219 contacts a portion of the first surface 216 of the substrate, the inner edge 231 of the outer joint members 221, the first and second edges 241, 243 of the image sensor die 202, and the outer edge 237 of the inner joint members 222. For example, the inner molding 219 may extend between the inner edge 231 of the outer joint members 221 and the first and second edges 241, 243 of the image sensor die 202 in the direction A2. Also, the inner molding 219 may extend between the inner edge 231 of the outer joint members 221 and the inner edge 235 of the inner joint members 222 in the direction A2. The inner molding 219 may extend between the first surface 216 of the substrate 204 and the conductive traces 220 on the light-transmitting member 208 in the direction A1. In some examples, the outer molding 217 includes one or more materials different from the material of the inner molding 219. In some examples, the outer molding 217 includes one or more materials that is/are the same as the material of the inner molding 219.

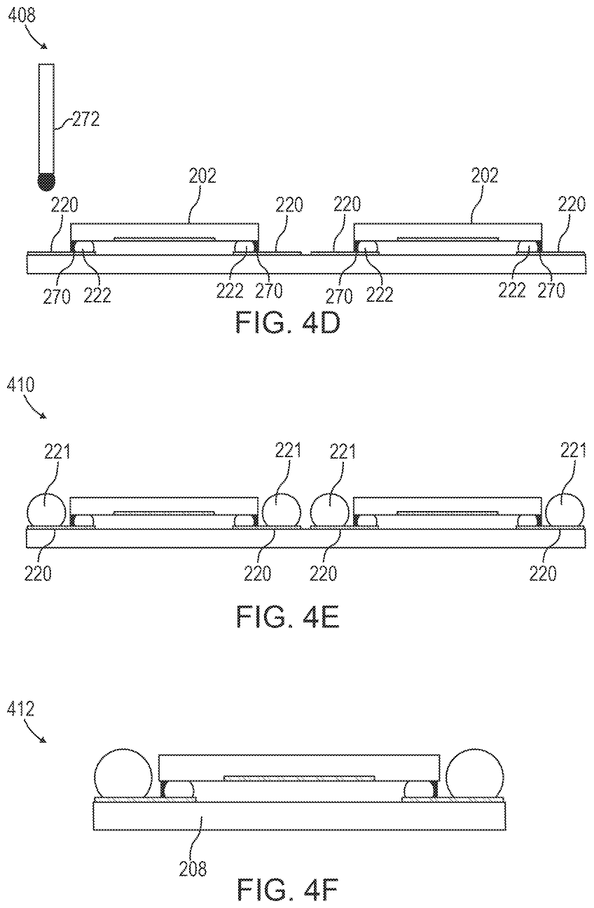

FIG. 3 illustrates an image sensor package 300 according to an aspect. The image sensor package 300 may be an example of the image sensor package 100 of FIG. 1 and/or the image sensor package 200 of FIG. 2 and may include any of the details discussed herein.

The image sensor package 300 includes a substrate 304, an image sensor die 302 coupled to the substrate 304, a light-transmitting member 308, inner joint members 322 disposed between the light-transmitting member 308 and the image sensor die 302, and outer joint members 321 disposed between the light-transmitting member 308 and the substrate 304. As shown in FIG. 3, in some examples, the inner joint members 322 may be conductive pillars. The conductive pillars may be a post (e.g., a linear post). The conductive pillars may include one or more types of metallic materials. In some examples, the conductive pillars include copper pillars. Also, in some examples, the outer joint members 321 may be conductive ball members (e.g., solder balls). The image sensor package 300 includes conductive components 351 coupled to the substrate 304, where the conductive components 351 are configured to connect to an external device. The conductive components 351 may be conductive ball members (e.g., solder balls). The image sensor package 300 includes an encapsulation material 315 having an outer molding 317 that contacts the outer joint members 321, the substrate 304, and the light-transmitting member 308, and an inner molding 319 that is disposed between the outer joint members 321 and the inner joint members 322.

The substrate 304 includes a dielectric material. In some examples, the substrate 304 includes a single layer of dielectric material. In some examples, the substrate 304 includes multiple layers of dielectric material. In some examples, the substrate 304 includes a printed circuit board (PCB) substrate (e.g., a single layer of PCB or multiple layers of PCB). In some examples, the substrate 304 includes a copper clad laminate (CCL) substrate.

The substrate 304 includes a first surface 316 and a second surface 318 that is disposed opposite to the first surface 316. The second surface 318 may be parallel with the first surface 316. The distance between the first surface 316 and the second surface 318 may define the thickness of the substrate 304 in a direction A1. The substrate 304 includes a first edge 353 and a second edge 355. The second edge 355 may be parallel to the first edge 353. The first edge 353 and the second edge 355 may be perpendicular to the first surface 316 and the second surface 318. The distance between the first edge 353 and the second edge 355 may define a length of the substrate 304 in a direction A2.

The image sensor die 302 includes a first surface 324 and a second surface 326. The second surface 326 is disposed in parallel with the first surface 324. The distance between the first surface 324 and the second surface 326 may define the thickness of the image sensor die 302 in the direction A1. The image sensor die 302 includes a first edge 341 and a second edge 343. The second edge 343 is disposed in parallel with the first edge 341. The distance between the first edge 341 and the second edge 343 may define a length of the image sensor die 302 in the direction A2.

The image sensor die 302 includes an active region 301. The active region 301 is defined on a portion of the first surface 324 of the image sensor die 302. The active region 301 includes, or corresponds with, an array of pixel elements configured to convert electromagnetic radiation (e.g., light) to electrical signals. An area outside of the active region 301 may be considered a non-active region. In some examples, the image sensor die 302 includes a complementary metal-oxide semiconductor (CMOS) image sensor. The image sensor die 302 is coupled to the substrate 304. For example, the second surface of the image sensor die 302 is coupled to the first surface 316 of the substrate 304. In some examples, the image sensor die 302 is coupled to the substrate 304 via a bonding material (e.g., a die attach film). The image sensor die 302 is coupled to the substrate 304 in a flip-chip configuration (e.g., using the inner joint members 322 and the outer joint members 321, and conductive traces 320 that connect the outer joint members 321 to the inner joint members 322).

The light-transmitting member 308 is coupled to the image sensor die 302 such that the light-transmitting member 308 is positioned over (and spaced apart from) the active region 301 of the image sensor die 302 in the direction A1. The light-transmitting member 308 includes a first surface 328 and a second surface 330. The second surface 330 is disposed in parallel with the first surface 328. The distance between the first surface 328 and the second surface 330 may define the thickness of the light-transmitting member 308 in the direction A2. The light-transmitting member 308 includes a first edge 307 and a second edge 309. The second edge 309 is disposed in parallel with the first edge 307. The distance between the first edge 307 and the second edge 309 may define a length of the light-transmitting member 308 in the direction A2.

Conductive traces 320 are coupled to the light-transmitting member 308. Conductive traces 320 are coupled to the second surface 330 of the light-transmitting member 308. The conductive traces 320 may be metallic traces such as copper traces, aluminum traces, and/or so forth. In some examples, a conductive trace 320 includes multiple types of metals. In some examples, the conductive traces 320 are formed on the light-transmitting member 308 via a lithography process. In some examples, a conductive trace 320 is coupled to the second surface 330 at a location between the first edge 307 and a central region 305 of the light-transmitting member 308, and a conductive trace 320 is coupled to the second surface 330 at a location between the second edge 309 and the central region 305. The central region 305 is an area of the light-transmitting member 308 that is devoid of conductive traces 320. The central region 305 is an area of the light-transmitting member 308 that passes light to the active region 301 of the image sensor die 302.

The outer joint members 321 and the inner joint members 322 are used to position the light-transmitting member 308 away from the active region 301 of the image sensor die 302 to route (e.g., electrically route) signals from the image sensor die 302 to the substrate 304. As shown in FIG. 3, inner joint members 322 are conductive pillars, and the outer joint members 321 are conductive ball members (e.g., solder balls). The conductive ball members of the outer joint members 321 may have a size (e.g., diameter, height in the direction A1, and/or width in the direction A2) that is larger than the size of the conductive pillars of the inner joint members 322.

The inner joint members 322 are coupled to the first surface 324 of the image sensor die 302 and the conductive traces 320 on the light-transmitting member 308. The inner joint members 322 may be coupled to the non-active area of the image sensor die 304. The inner joint members 322 include an inner edge 335 and an outer edge 337. In some examples, the inner edge 335 includes a linear portion. In some examples, the entirety of the inner edge 335 is linear. The outer edge 337 may include a linear portion. In some examples, the entirety of the outer edge 337 is linear. In some examples, a conductive trace 320 may be coupled to the first surface 324 at a location between the first edge 341 and the active region 301 of the image sensor die 302, and a conductive trace 320 may be coupled to the first surface 324 at a location between the second edge 343 and the active region 301 of the image sensor die 302. The height of the inner joint members 322 (in the direction A1) may define (at least in part) the gap height (e.g., the height of empty space 303 between the active region 301 and the second surface 330 of the light-transmitting member 308).

The outer joint members 321 are coupled to the first surface 316 of the substrate 304 and the conductive traces 320 on the light-transmitting member 308. The outer joint members 321 include an inner edge 331 and an outer edge 333. The inner edge 331 may include a linear portion. In some examples, the entirety of the inner edge 331 is linear. The outer edge 333 may include a linear portion. In some examples, the entirety of the outer edge 333 is linear. In some examples, a conductive trace 320 may be coupled to the first surface 316 at a location between the first edge 353 of the substrate 304 and the first edge 341 of the image sensor die 302, and a conductive trace 320 may be coupled to the first surface 316 at a location between the second edge 355 of the substrate 304 and the second edge 343 of the image sensor die 302. The height of the outer joint members 321 (in the direction A1) may define (at least in part) the distance between the first surface 316 of the substrate 304 and the second surface 330 of the light-transmitting member 308. The outer joint members 321 may have a height greater than the height of the inner joint members 322 in the direction A2. In some examples, the outer joint members 321 may be a width greater than the width of the inner joint members 322 in the direction A2.

The image sensor package 300 includes conductive components 351 coupled to the second surface 318 of the substrate 304. In some examples, the conductive components 351 are surface-mount packaging elements. In some examples, the conductive components 351 include solder balls. The conductive components 351 are components used to connect to an external device (e.g., a ball grid array (BGA) device). However, the conductive components 351 may include other types of surface-mount packaging elements. In some examples, the conductive components 351, the inner joint members 322, and the outer joint members 321 are conductive (solder) balls, which may include the same type of material(s). In some examples, the conductive components 351 have a size that is larger than the inner joint members 322 and smaller than the outer joint members 321.

The image sensor package 300 includes an encapsulation material 315. The encapsulation material 315 may include one or more molding materials (e.g., in a molding compound if including multiple types of materials). For example, the molding material(s) may include a metal, a plastic, a resin, an epoxy, a phenolic hardener, a silica material, a pigment, a glass, a ceramic casing, and/or so forth.

The encapsulation material 315 may include an outer molding 317 that contacts the substrate 304, the outer joint members 321 and the light-transmitting member 308. For example, the outer molding 317 contacts a portion (e.g., a perimeter portion) of the first surface 316 of the substrate 304, the outer edge 333 of the outer joint members 321, and at least a portion of the first and second edges 307, 309 of the light-transmitting member 308. In some examples, the outer molding 317 extends along the entirety of the first and second edges 307, 309 of the light-transmitting member 308. In some examples, although not shown in FIG. 3, the outer molding 317 may extend and contact at least a portion of the first surface 328 of the light-transmitting member 308.

In some examples, the outer molding 317 defines a first molding edge 332 that defines an end of the outer molding 317 in the direction A2. In some examples, the first molding edge 332 is linear. In some examples, the first molding edge 332 includes one or more angled or curved portions. In some examples, at least a portion of the first molding edge 332 (or all of the first molding edge 332) is aligned with the direction A1. In some examples, the first molding edge 332 is disposed at an angle with respect to the direction A2. In some examples, at least a portion of the first molding edge 332 (or all of the first molding edge 332) is aligned with the first edge 353 (or the second edge 355) of the substrate 304. In some examples, the first molding edge 332 is disposed at a location between the first edge 353 (or the second edge 355) of the substrate 304 and the outer edge 333 of the outer joint members 321.

The outer molding 317 may define a second molding edge 334 defining an end of the outer molding 317 in the direction A1. The second molding edge 334 may extend from the first molding edge 332 to the first and second edges 307, 309 of the light-transmitting member 308. In some examples, the second molding edge 334 is disposed at a non-zero angle with respect to the first molding edge 332. In some examples, the second molding edge 334 is disposed at an angle that is perpendicular to the first molding edge 332. In some examples, the second molding edge 334 is linear. In some examples, the second molding edge 334 includes one or more bent or curved portions.

The encapsulation material 315 may include an inner molding 319 that contacts and extends between the inner joint members 322 and the outer joint members 321. For example, the inner molding 319 contacts a portion of the first surface 316 of the substrate, the inner edge 331 of the outer joint members 321, the first and second edges 341, 343 of the image sensor die 302, and the outer edge 337 of the inner joint members 322. For example, the inner molding 319 may extend between the inner edge 331 of the outer joint members 321 and the first and second edges 341, 343 of the image sensor die 302 in the direction A3. Also, the inner molding 319 may extend between the inner edge 331 of the outer joint members 321 and the inner edge 335 of the inner joint members 322 in the direction A2. The inner molding 319 may extend between the first surface 316 of the substrate 304 and the conductive traces 320 on the light-transmitting member 308 in the direction A1. In some examples, the outer molding 317 includes one or more materials different from the material of the inner molding 319. In some examples, the outer molding 317 includes one or more materials that is/are the same as the material of the inner molding 319.

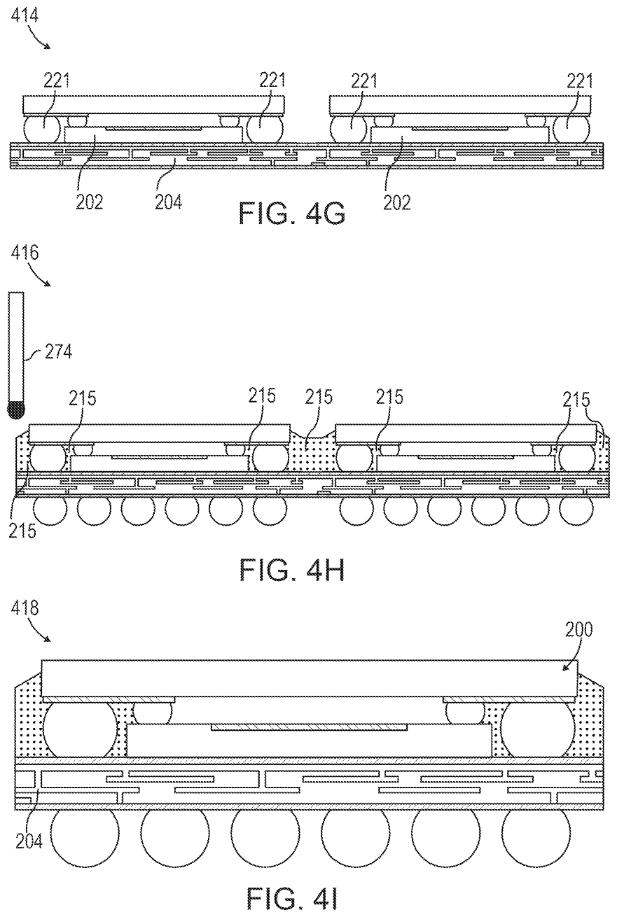

FIGS. 4A through 4I illustrate a process flow depicting example operations of assembling an image sensor package. Although the process flow of FIGS. 4A through 4I illustrates operations in sequential order, it will be appreciated that this is merely an example, and that additional or alternative operations may be included. Further, operations of FIGS. 4A through 4I and related operations may be executed in a different order than that shown, or in a parallel or overlapping fashion. Although the process flow of FIGS. 4A through 4I is explained with reference to the image sensor package 200 of FIG. 2, the process flow of FIGS. 4A through 4I may be applicable to other image sensor packages.

Referring to FIG. 4A, operation 402 includes receiving a light-transmitting member 208 and an image sensor assembly substrate 285 defining a plurality of image sensor dies 202. Referring to FIG. 4B, operation 404 includes grinding the wafer of the image sensor assembly substrate 285 and cutting the image sensor assembly substrate 285 to obtain individual image sensor dies 202. Also, operation 404 includes forming the conductive traces 220 on the light-transmitting member 208. For example, a lithography process may be performed on the light-transmitting member 208 to form metal plating on the glass substrate. Further, operation 404 includes forming inner joint members 222 on the conductive traces 220. In some examples, a bumping method may be performed to create the inner joint members 222. In some examples, as shown in FIG. 4B, the inner joint members 222 may be conductive ball members (e.g., solder balls). In some examples, the inner joint members 222 may be conductive pillars as shown in FIG. 3. In some examples, the bumping method could be solder balls pick and placement with flux and reflow, or plated micro bumps or plated, copper pillars with solder post.

Referring to FIG. 4C, operation 406 includes coupling the image sensor dies 202 to the inner joint members 222. For example, the image sensor dies 202 may be bonded (e.g., flip-chip bonded) on the light-transmitting member 208 with flux and reflow. Referring to FIG. 4D, operation 408 includes applying, by a dispenser 272, an underfill material 270 to seal the gaps of the inner joint members 222, where the underfill material 270 is cured with heat. In some examples, the underfill material 270 may include an epoxy resin. In some examples, the underfill material 270 may include an epoxy resin with high viscosity and low flowability. Referring to FIG. 4E, operation 410 includes mounting the outer joint members 221 to the conductive traces 220. Referring to FIG. 4F, operation 412 includes cutting the light-transmitting member 208 to create individual singulated parts, where each singulated part includes a single image sensor die 202 coupled to the light-transmitting member 208 via the inner joint members 222.

Referring to FIG. 4G, operation 414 includes coupling each singulated part to the substrate 204. For example, the image sensor die 202 and the outer joint members 221 are coupled to the substrate 204, which may include applying the flux on the substrate lead and performing a reflow process. Referring to FIG. 4H, operation 416 includes applying an encapsulation material 215 to the image sensor package. For example, operation 416 may include applying a liquid encapsulation to fill the space between the inner joint members 222 and the outer joint members 221 and the space between the singulated parts, where the liquid encapsulation is cured with heat. Referring to FIG. 4I, operation 418 includes cutting the encapsulation material 215 and the substrate 204 between the individual singulated parts to create individual image sensor packages.

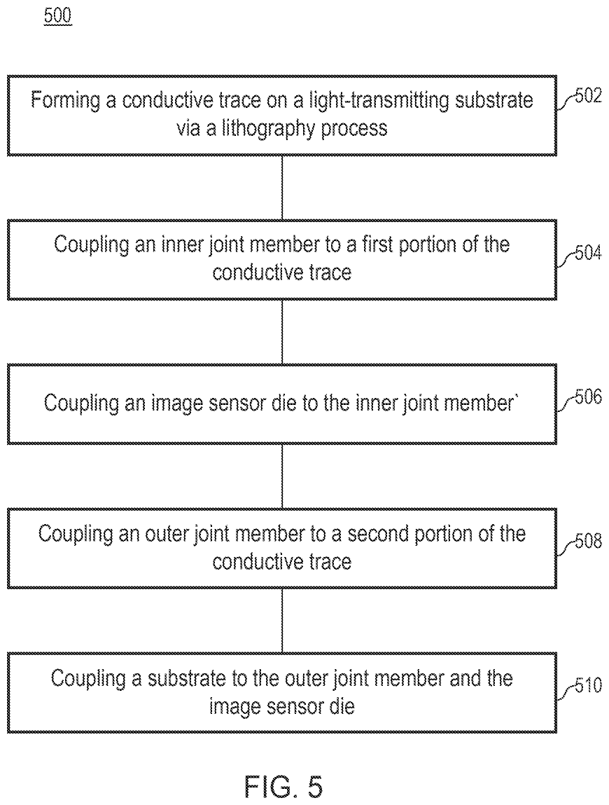

FIG. 5 depicts a flowchart 500 having example operations for assembling an image sensor package according to an aspect. Although the flowchart 500 is explained with the image sensor package 100 of FIG. 1, the flowchart 500 may be applicable to any of the embodiments discussed herein. Although the flowchart 500 of FIG. 5 illustrates operations in sequential order, it will be appreciated that this is merely an example, and that additional or alternative operations may be included. Further, operations of FIG. 5 and related operations may be executed in a different order than that shown, or in a parallel or overlapping fashion.

Operation 502 includes forming a conductive trace 120 on a light-transmitting member 108 via a lithography process. Operation 504 includes coupling an inner joint member 122 to a first portion of the conductive trace 120. Operation 506 includes coupling an image sensor die 102 to the inner joint member 122. Operation 508 includes coupling an outer joint member 121 to a second portion of the conductive trace 120. Operation 510 includes coupling a substrate 104 to the outer joint member 121 and the image sensor die 102.

It will be understood that, in the foregoing description, when an element is referred to as being connected to, electrically connected to, coupled to, or electrically coupled to another element, it may be directly connected or coupled to the other element, or one or more intervening elements may be present. In contrast, when an element is referred to as being directly connected to or directly coupled to another element, there are no intervening elements. Although the terms directly connected to, or directly coupled to may not be used throughout the detailed description, elements that are shown as being directly connected or directly coupled can be referred to as such. The claims of the application, if any, may be amended to recite exemplary relationships described in the specification or shown in the figures. Implementations of the various techniques described herein may be implemented in (e.g., included in) digital electronic circuitry, or in computer hardware, firmware, software, or in combinations of them. Portions of methods also may be performed by, and an apparatus may be implemented as, special purpose logic circuitry, e.g., an FPGA (field programmable gate array) or an ASIC (application specific integrated circuit).

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. An image sensor package comprising:
a substrate;
an image sensor die coupled to the substrate;
a light-transmitting member;
an inner joint member disposed between the light-transmitting member and the image sensor die; and
an outer joint member disposed between the light-transmitting member and the substrate.

2. The image sensor package of claim 1, further comprising:
a conductive trace coupled to a surface of the light-transmitting member, the conductive trace being coupled to the inner joint member and the outer joint member.

3. The image sensor package of claim 1, wherein the image sensor die is coupled to the substrate in a flip-chip configuration.

4. The image sensor package of claim 1, wherein the inner joint member has a size smaller than a size of the outer joint member.

5. The image sensor package of claim 1, wherein the inner joint member includes a conductive ball member.

6. The image sensor package of claim 1, wherein the inner joint member includes a conductive pillar.

7. The image sensor package of claim 1, wherein the outer joint member includes a conductive ball member.

8. The image sensor package of claim 1, further comprising:
an encapsulation material disposed between the inner joint member and the outer joint member.

9. The image sensor package of claim 1, wherein the image sensor package is an interstitial ball grid array (iBGA) package.

10. An image sensor package comprising:
a substrate;
an image sensor die coupled to the substrate, the image sensor die having an active region and a non-active region;
a light-transmitting member having a first surface and second surface;
a conductive trace coupled to the second surface of the light-transmitting member;
an inner joint member disposed between and connected to the non-active region of the image sensor die and the conductive trace; and
an outer joint member disposed between and connected to the conductive trace and the substrate.

11. The image sensor package of claim 10, wherein the image sensor die is a complementary metal oxide semiconductor (CMOS) image sensor die, and the CMOS image sensor die is coupled to the substrate in a flip-chip configuration.

12. The image sensor package of claim 10, wherein the inner joint member includes a conductive ball member.

13. The image sensor package of claim 10, wherein the inner joint member includes a conductive pillar.

14. The image sensor package of claim 10, wherein the outer joint member includes a conductive ball member.

15. The image sensor package of claim 10, further comprising:
an encapsulation material, the encapsulation material including an inner molding disposed between the inner joint member and the outer joint member, the encapsulation material including an outer molding that contacts edges of the light-transmitting member.

16. The image sensor package of claim 10, wherein the substrate includes a first surface and a second surface, the first surface of the substrate being coupled to the image sensor die, the image sensor package further comprising:
a plurality of conductive components coupled to the second surface of the substrate, the plurality of conductive components configured to be coupled to an external device.

17. The image sensor package of claim 10, wherein the image sensor package is devoid of bond wires.

18. A method for assembling an image sensor package, the method comprising:
forming a conductive trace on a light-transmitting member via a lithography process;
coupling an inner joint member to a first portion of the conductive trace;
coupling an image sensor die to the inner joint member;
coupling an outer joint member to a second portion of the conductive trace; and
coupling a substrate to the outer joint member and the image sensor die.

19. The method of claim 18, further comprising:
applying an encapsulation material to the image sensor package, the encapsulation material including an inner molding disposed between the outer joint member and the inner joint member.

20. The method of claim 19, wherein the inner joint member includes a conductive ball member or a conductive pillar, and the outer joint member includes a conductive ball member.
